(19) United States
(12) Patent Application Publication
(10) Pub. No.: US 2024/0306416 A1
(43) Pub. Date: Sep. 12, 2024

(54) LIGHT EMITTING DEVICE AND DISPLAY APPARATUS

(71) Applicant: BOE Technology Group Co., Ltd., Beijing (CN)

(72) Inventor: Erli Li, Beijing (CN)

(73) Assignee: BOE Technology Group Co., Ltd., Beijing (CN)

(21) Appl. No.: 18/020,732

(22) PCT Filed: May 23, 2022
(86) PCT No.: PCT/CN2022/094407

§ 371 Date: Feb. 10, 2023

(51) Int. Cl. H10K 50/15; H10K 50/18; H10K 101/30; H10K 101/40

(52) U.S. Cl. CPC H10K 50/156; H10K 50/181; H10K 2101/30; H10K 2101/40

(57) ABSTRACT

The present application provides a light emitting device and a display apparatus. The light emitting device includes: an anode; an emission layer located on a side of the anode; and a hole auxiliary layer located between the anode and the emission layer. At least one of the emission layer and the hole auxiliary layer includes a functional material that is configured to be crystallizable at a preset temperature and improve hole injection property.

### CROSS-REFERENCE TO RELATED APPLICATIONS

The present application is a U.S. National Stage of International Application No. PCT/CN2022/094407, filed on May 23, 2022, the contents of which are incorporated herein by reference in its entirety.

### TECHNICAL FIELD

The present application relates to the field of display technology, in particular to a light emitting device and a display apparatus.

### BACKGROUND

OLED (Organic Light-Emitting Diode) light emitting device is popular in the market due to its performances of active light emission, high luminous brightness, high resolution, wide viewing angle, fast response speed, low energy consumption and flexibility. In the related art, when the OLED light emitting device is used under high-temperature conditions, a process of hole injection into the emission layer of the OLED light emitting device is hindered due to the aging of the material caused by high temperature, so that the injections of holes and electrons in the emission layer are out of balance. Accordingly, the luminous efficiency of the OLED light emitting device decreases.

### SUMMARY

Embodiments of the present application adopt technical solutions below.

In a first aspect, embodiments of the present application provide a light emitting device, including:
an anode;
an emission layer located on a side of the anode;
a hole auxiliary layer located between the anode and the light emitting layer;
where at least one of the emission layer and the hole auxiliary layer includes a functional material, and the functional material is configured to be crystallizable at a preset temperature and improve hole injection property.

In some embodiments of the present application, the preset temperature is greater than or equal to 105° C.

In some embodiments of the present application, a glass transition temperature of the functional material is less than 105° C.

In some embodiments of the present application, the material of the emission layer includes the functional material, a guest material and at least one host material.

In some embodiments of the present application, a proportion of the functional material in the material of the emission layer is in a range of 0.1% to 0.2%.

In some embodiments of the present application, a material of the emission layer includes at least two host materials, and absolute value of a difference of the highest occupied molecular orbital (HOMO) energy value of each two host materials is less than or equal to 0.1 eV.

In some embodiments of the present application, the hole auxiliary layer includes a first hole transport sublayer and a hole injection sublayer, and the hole injection sublayer is located on a side of the first hole transport sublayer facing away from the emission layer; where the material of the first hole transport sublayer includes a hole transport material and the functional material.

In some embodiments of the present application, a proportion of the functional material in the materials of the first hole transport sublayer is in a range of 20% to 30%.

In some embodiments of the present application, the hole auxiliary layer includes a first hole transport sublayer, a second hole transport sublayer and a hole injection sublayer, and the hole injection sublayer is located on a side of the first hole transport sublayer facing away from the second hole transport sublayer, the second hole transport sublayer is located between the first hole transport sublayer and the emission layer; and

at least one of the first hole transport sublayer and the second hole transport sublayer includes the functional material.

In some embodiments of the present application, the first hole transport sublayer includes a hole transport material, and the second hole transport sublayer includes the functional material. A ratio of a thickness of the second hole transport sublayer in a direction perpendicular to the emission layer to a thickness of the first hole transport sublayer in the direction perpendicular to the emission layer is less than or equal to 3:7.

In some embodiments of the present application, the hole auxiliary layer includes an electron blocking sublayer, a first hole transport sublayer and a hole injection sublayer, and the first hole transport sublayer is located on a side of the electron blocking sublayer layer facing away from the emission layer, the hole injection sublayer is located between the first hole transport sublayer and the anode; and

the material of the electron blocking sublayer includes an electron blocking material and the functional material.

In some embodiments of the present application, the proportion of the functional material in the material of the electron blocking sublayer is in a range of 2% to 3%.

In some embodiments of the present application, the functional material includes a compound with a planar configuration.

In some embodiments of the present application, the functional material includes a combination of one or more of butadiene compounds, alkoxy-substituted diphenylamine compounds, and coupled triphenylamine compounds.

In some embodiments of the present application, the light emitting device further includes a cathode located on a side of the emission layer facing away from the hole auxiliary layer.

In a second aspect, embodiments of the present application provide a display apparatus including the light emitting device as described above.

The above description is only a summary of solutions of the present disclosure. In order to learn technical means of the present disclosure more clearly and allow the technical means to be implemented based on the disclosure of the description, and in order to make the above and other objects, features and advantages of the present disclosure more obvious and understandable, specific embodiments of the present disclosure are illustrated below.

### BRIEF DESCRIPTION OF THE DRAWINGS

In order to clearly explain technical solutions of embodiments of the present disclosure, drawings required in the description of the embodiments or the related art are briefly introduced below. Apparently, the drawings in the following description are only some embodiments of the present disclosure. For those of ordinary skill in the art, other drawings can be obtained based on these drawings without paying creative work.

FIG. 1 is a structural schematic diagram illustrating a light emitting device provided by embodiments of the present application;

FIG. 2 is a structural schematic diagram illustrating a light emitting device provided by embodiments of the present application;

FIG. 3 is a structural schematic diagram illustrating a light emitting device provided by embodiments of the present application:

FIG. 4 is a structural schematic diagram illustrating a light emitting device provided by embodiments of the present application;

FIG. 5 is a diagram illustrating a comparison between crystallization properties of materials in the related art and crystallization properties of functional materials provided by embodiments of the present application;

FIG. 6 illustrates impedance spectrum data of the light emitting device in the related art before the high temperature storage test;

FIG. 7 illustrates impedance spectrum data of the light emitting device in the related art after the high temperature storage test;

FIG. 8 is a efficiency change comparison chart of the light emitting device provided by embodiments of the present application and the light emitting device in the related art as high-temperature storage time increases; and

FIG. 9 is a voltage change comparison chart of the light emitting device provided by embodiments of the present application and the light emitting device in the related art as high-temperature storage time increases.

### DETAILED DESCRIPTION OF THE EMBODIMENTS

The technical solutions of the embodiments of the present application will be described below with reference to the accompanying drawings of the embodiments of the present application. Apparently, only a part of the embodiments, not all the embodiments of the present application, are described. All other embodiments obtained, based on the embodiments described in the present application, by those skilled in the art without paying creative efforts shall fall within the protection scope of the present application.

In the drawings, the thicknesses of regions and layers may be exaggerated for clarity. The same reference numerals in the drawings are used for denoting the same or similar structures, and thus detailed descriptions thereof will be omitted. Furthermore, the drawings are merely schematic illustrations of the present application and are not necessarily drawn to scale.

The term “comprising” throughout the specification and claims is interpreted in an open and inclusive sense, i.e., “including, but not limited to”, unless it is otherwise specified in the context. In the description of the specification, the terms such as “an embodiment”, “some embodiments”, “exemplary embodiments”, “example”, “specific examples” or “some examples” are intended to indicate that particular features, structures, materials, or characteristics related to the embodiment or example are included in at least one embodiment or example of the present application. Schematic representations of the above terms are not necessarily referring to the same embodiment or example. Furthermore, the particular features, structures, materials or characteristics described may be included in any one or more embodiments or examples in any suitable manner.

In recent years, as a new type of flat-panel display, an organic electroluminescence display such as an organic light emitting diode (OLED) display has gradually received more attention. The organic electroluminescence display has become a popular mainstream display product in the market due to its characteristics of active light emission, high luminous brightness, high resolution, wide viewing angle, fast response, low energy consumption and flexibility.

An organic electroluminescent device is an important component of an organic electroluminescent display. Generally, an organic electroluminescent device includes an anode, an emission layer and a cathode. In order to improve the performance of the organic electroluminescent device, some organic functional layers such as a hole injection layer, a hole transport layer, an electron injection layer and an electron transport layer can also be incorporated. When the cathode and the anode are applied with a forward voltage, holes are injected into the emission layer from the anode, and electrons are injected into the emission layer from the cathode. In the emission layer, holes and electrons recombine to form excitons. A luminescence phenomenon will occur when the excitons transit from an excited state to a ground state, that is, electroluminescence. The brightness and performance of the organic electroluminescent device are related to factors such as energy level matching of the hole transport layer and adjacent functional layers, the balance of electrons and holes injected by carriers. The hole transport material needs to have a high hole mobility, a suitable HOMO/LUMO level and thermal stability. Generally, the energy level difference between the hole transport layer and adjacent functional layers is also considered to have a significant relationship with the device efficiency and stability. If the HOMO energy level difference between the hole transport layer and the hole injection layer is too large, the initial voltage of the device will increase, and the service life of the device is reduced. A large HOMO energy level difference between the host material of the emission layer and the hole transport layer will also prevent holes from being transported to the emission layer. The highest occupied molecular orbital (HOMO) energy level reflects strength of the molecule's ability to lose electrons. The higher the energy value of the HOMO energy level, the easier it is for the substance to lose electrons, allowing holes to transport. The lowest unoccupied molecular orbital (LUMO) energy level reflects strength of the molecule's ability to obtain electrons. The lower the energy value of the LUMO energy level, the easier it is for the substance to obtain electrons, allowing electrons to transport.

When the electroluminescent device is used under high temperature conditions, the hole injection into the emission layer is hindered due to the aging of the hole transport material and the change of the interface of the organic layer, resulting in unbalance of hole injection and electron injection in the emission layer. Accordingly, the efficiency of the light emitting device is greatly reduced, thereby reducing the service life of the light emitting device. Therefore, for OLED display products used under high temperature conditions, it is particularly important to improve the hole transport capability to increase the service life.

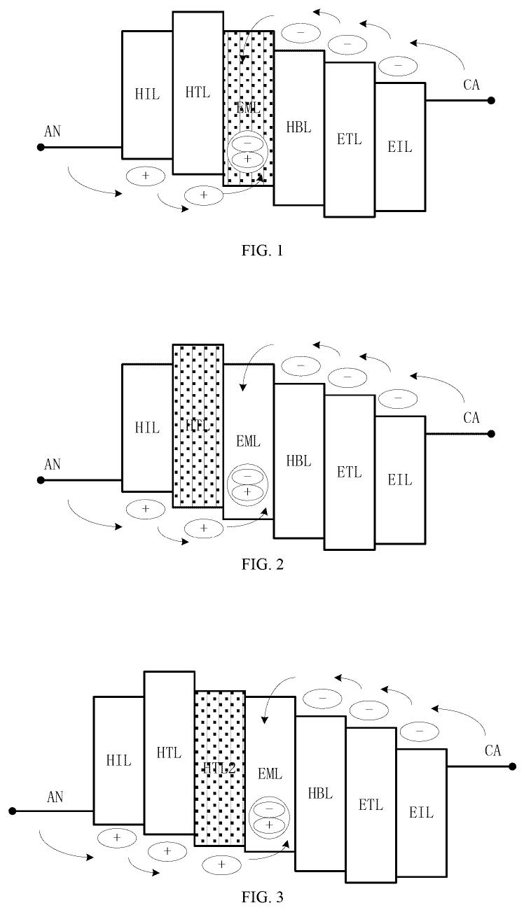

The embodiments of the present application provide a light emitting device, referring to FIG. 1-FIG. 4, the light emitting device includes:
an anode (AN);
an emission layer (EML) located on an side of the anode (AN);
a hole auxiliary layer located between the anode (AN) and the emission layer (EML);
where at least one of the emission layer (EML) and the hole auxiliary layer includes a functional material, and the functional material is configured to be crystallizable at a preset temperature and improve hole injection capability.

The specific material of the anode is not limited here, for example, the material of the anode may include indium tin oxide (ITO).

The emission color of the emission layer (EML) is not limited herein. Exemplarily, the emission color of the emission layer (EML) may be red; or, the emission color of the emission layer (EML) may be green; or, the emission color of the emission layer (EML) may be blue.

In an exemplary embodiment, the emission layer (EML) may include at least one host material.

For example, the emission layer (EML) includes one host material.

For another example, the emission layer (EML) includes two host materials. Exemplarily, one host material is an N-type host material, and the other host material is a P-type host material.

In an exemplary embodiment, the emission layer (EML) may include a guest material. Exemplarily, the guest material may be a thermally activated delayed fluorescent material (TADF).

It should be noted that, in FIGS. 1-4, those marked with “+” represent holes, and those marked with “−” represent electrons. The direction pointed by arrows represents a moving direction of holes or electrons.

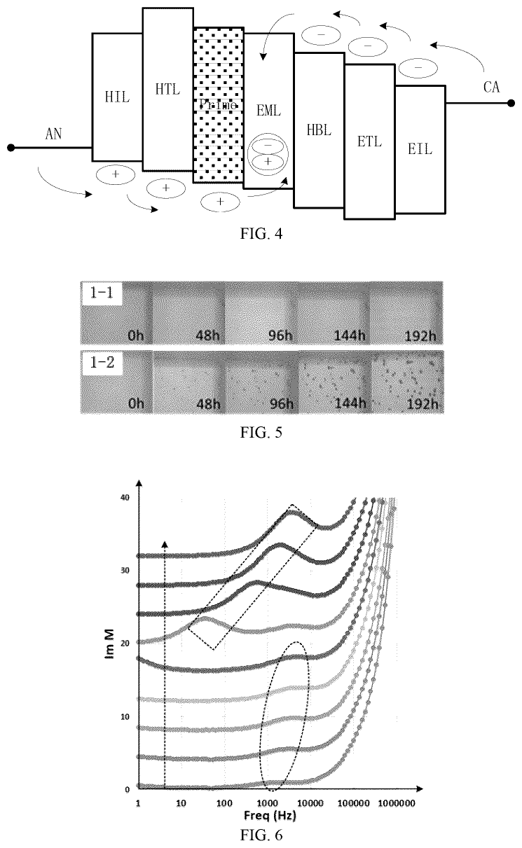

In exemplary embodiments, as shown in FIG. 1 or FIG. 2, the hole auxiliary layer may include a first hole transport sublayer (HTL) and a hole injection sublayer (HIL); or, as shown in FIG. 3, the hole auxiliary layer may include a first hole transport sublayer (HTL), a second hole transport sublayer (HTL2), and a hole injection sublayer (HIL); or, as shown in FIG. 4, the hole auxiliary layer may include an electron blocking sublayer (Prime), a first hole transport sublayer (HTL), and a hole injection sublayer (HIL).

At least one of the emission layer (EML) and the hole auxiliary layer includes functional materials, including but not limited to the followings:
the emission layer (EML) includes a functional material, and the hole auxiliary layer does not include the functional material; or
the emission layer (EML) does not include a functional material, and the hole auxiliary layer includes the functional material; or
the emission layer (EML) includes a functional material, and the hole auxiliary layer includes the functional material.

In an exemplary embodiment, in the case where the hole auxiliary layer includes a functional material, since the hole auxiliary layer includes a plurality of sublayers, at least one sublayer in the hole auxiliary layer includes the functional material.

The functional material can crystallize at a preset temperature and improve the hole injection property, and the preset temperature is greater than or equal to 105° C.

In some embodiments of the present application, a glass transition temperature (Tg) of the functional material is less than 105° C.

Exemplarily, the glass transition temperature (Tg) of the functional material may range from 95′C to 102° C.

That is to say, when being used at a temperature greater than or equal to 105° C., the molecular structure in the functional material can undergo chain segmental motion and regular arrangement to form a crystallization structure.

Compared with the light emitting devices in the related art, after being stored and used for a period of time under high temperature conditions, the hole transport material is easy to age due to high temperature, which causes the injection barrier at the interface to increase. The most significant difference is that the HOMO energy level difference between the hole transport layer and the emission layer increases. Accordingly, the injection rate of holes into the emission layer is significantly slowed down, and the unbalance between electron injection and hole injection as well as the mobility difference between the two intensify, so that the carriers injected from two electrodes cannot be effectively confined in the emission layer to form excitons and some excess carriers reach the electrodes, resulting in the quenching of light at the electrodes, and reducing the luminous efficiency and service life of the device.

In the embodiments of the present application, at least one of the emission layer and the hole auxiliary layer includes a functional material. The functional material has a crystallizing property of forming a crystallization structure at a high temperature of 105° C. and above, the crystallization structure can improve the hole transport rate of a film layer where the crystallization structure is located. Therefore, when the light emitting device is stored or used under high temperature conditions, the functional material can largely offset the problem that it is hard to transport holes to the emission layer due to the aging of the material of the hole transport sublayer, improving the injection effect of holes into the emission layer, improving and increasing the carrier balance in the emission layer. In this way, the hole injection and electron injection of the emission layer can maintain a relatively balanced state, which can effectively slow down the reduction of the efficiency of the light emitting device, thereby prolonging the service life of the light emitting device under high temperature conditions.

In some embodiments of the present application, as shown in FIG. 1, the material of the emission layer (EML) includes the functional material, a guest material and at least one host material.

It should be noted that, in FIG. 1 to FIG. 4 provided in the embodiments of the present application, a film layer filled with patterns represents that the film layer includes the functional material provided in the present application, which will not be repeated later.

In some embodiments of the present application, a proportion of the functional material in the material of the emission layer is in a range of 0.1% to 0.2%.

In an exemplary embodiment, a ratio of the proportions of the host material, the guest material and the functional material in the emission layer may be 97%: 2.9%: 0.1% or 96%: 3.8%: 0.2%.

In an exemplary embodiment, the above-mentioned guest material may be a thermally activated delayed fluorescent material.

The specific structure of the above-mentioned host material is not limited here, and may be determined according to actual conditions.

In addition, it should be noted that thermally activated delayed fluorescence is a process of thermally activated reluminescence of a triplet exciton, in which the triplet exciton is transited to a higher vibrational energy level after being thermally activated, and then reaches the vibrational energy level of the singlet state close to its energy level through reverse intersystem crossing (RISC), fluorescence is produced through the re-radiation. Compared with the direct emission of the singlet state, the fluorescence is delayed, and is called as delayed fluorescence. To ensure efficient reverse intersystem crossing (RISC), generally, thermally activated delayed fluorescent materials have small triplet and singlet energy gaps.

The specific structure of the above-mentioned guest material is not limited here, and may be determined according to actual conditions.

In the embodiments of the present application, by doping the material of the emission layer with a functional material, the functional material in the emission layer can crystallize after the light emitting device is stored or used at high temperature for a period of time. The crystallization structure can improve the high-temperature resistance performance of the emission layer and improve the injection efficiency of holes into the emission layer, improve and enhance the carrier balance in the emission layer, so that the hole injection and electron injection of the emission layer can maintain a relatively balanced state. Therefore, the reduction of the efficiency of the light emitting device is effectively slow down, thereby prolonging the service life of the light emitting device under high temperature conditions.

In some embodiments of the present application, the material of the emission layer (EML) includes at least two host materials, and absolute value of a difference of the highest occupied molecular orbital (HOMO) energy value of each two host materials is less than or equal to 0.1 eV.

In an exemplary embodiment, the material of the emission layer (EML) further includes two host materials, and the absolute value of the difference of the highest occupied molecular orbital (HOMO) energy values of the two host materials is less than or equal to 0.1 eV. When the material of the emission layer (EMIL) includes two host materials, a ratio of the proportions of the two host materials may be in a range of 7:3 to 5:5.

It should be noted that, assuming that the material of the emission layer includes multiple host materials, the multiple host materials can be mixed first before forming the emission layer, and then be vapor deposited; or, the emission layer can be prepared by a mixed evaporation process.

In an embodiment of the present application, in the case where the material of the emission layer (EML) includes at least two host materials, by setting the absolute value of the difference of the highest occupied molecular orbital (HOMO) energy value between every two host materials to be less than or equal to 0.1 eV, when stored or used at high temperature, due to the energy level difference of various host materials, the attenuation degrees of the hole transport rate of various host materials are different, that is to say, the aging rates are different. In this way, the overall aging rate of the light emitting device can be further delayed, so that the difference between the transport rate of holes and that of electrons is kept within a certain value range, thereby improving and increasing the carrier balance in the emission layer, and improving the service life of the device at high temperature.

In some embodiments of the present application, as shown in FIG. 2, the hole auxiliary layer includes a first hole transport sublayer (HTL) and a hole injection sublayer (HIL), and the hole injection sublayer (HIL) is located on a side of the first hole transport sublayer (HTL) facing away from the emission layer (EML). Materials of the first hole transport sublayer (HTL) include a hole transport material and the functional material.

In some embodiments of the present application, a proportion of the functional material in the materials of the first hole transport sublayer (HTL) is in a range of 20% to 30%.

In an exemplary embodiment, the materials of the first hole transport sublayer (HTL) include a hole transport material and the functional material, and a ratio of the proportions of the hole transport material and the functional material can be 8:2 or 7:3.

The structure of the hole transport material included in the first hole transport sublayer (HTL) is not limited here, and may be determined according to actual conditions.

The structure of the material of the hole injection sublayer (HIL) is not limited here, and may be determined according to actual conditions.

In the embodiment of present application, by doping the functional material in the first hole transport sublayer (HTL) as shown in FIG. 2, the functional material in the first hole transport sublayer (HTL) can crystallize to form a crystallization structure after the light emitting device is stored or used at high temperature for a period of time. The crystallization structure can delay the aging of the hole transport material of the first hole transport sublayer, thereby improving the problem that holes are hard to transport to the emission layer due to the aging of the hole transport material, and improving the effect of the hole transport and injection into the emission layer. Therefore, the hole injection and the electron injection in the emission layer can maintain a relatively balanced state, which can effectively slow down the reduction of the efficiency of the light emitting device, thereby prolonging the service life of the light emitting device under high temperature conditions.

In some embodiments of the present application, as shown in FIG. 3, the hole auxiliary layer includes a first hole transport sublayer (HTL), a second hole transport sublayer (HTL2) and a hole injection sublayer (HIL). The hole injection sublayer (HIL) is located on a side of the first hole transport sublayer (HTL) facing away from the second hole transport sublayer (HTL2), and the second hole transport sublayer (HTL2) is located between the first hole transport sublayer (HTL) and the emission layer (EML).

At least one of the first hole transport sublayer (HTL) and the second hole transport sublayer (HTL2) includes the functional material.

In an exemplary embodiment, at least one of the first hole transport sublayer (HTL) and the second hole transport sublayer (HTL2) includes the functional material, including but not limited to the following:
the first hole transport sublayer (HTL) includes the functional material, and the second hole transport sublayer (HTL2) does not include the functional material; or
the first hole transport sublayer (HTL) does not include the functional material, and the second hole transport sublayer (HTL2) includes the functional material; or
the first hole transport sublayer (HTL) includes the functional material, and the second hole transport sublayer (HTL2) also includes the functional material.

In some embodiments of the present application, the first hole transport sublayer (HTL) includes the hole transport material, and the second hole transport sublayer (HTL2) includes the functional material. The ratio of the thickness of the second hole transport sublayer (HTL2) in a direction perpendicular to the emission layer (EML) to the thickness of the first hole transport sublayer (HTL) in the direction perpendicular to the emission layer (EML) is less than or equal to 3:7.

In some embodiments, as shown in FIG. 3, the material of the first hole transport sublayer (HTL) is the hole transport material, and the material of the second hole transport sublayer (HTL2) is the functional material. That is to say, merely the second hole transport sublayer (HTL2) is formed through vapor deposition by using the functional material as a raw material, and the material of the first hole transport sublayer (HTL) does not contain the functional material.

In an exemplary embodiment, a sum of the thickness of the second hole transport sublayer (HTL2) in the direction perpendicular to the emission layer (EML) and the thickness of the first hole transport sublayer (HTL) in the direction perpendicular to the emission layer EML is d, where the thickness of the second hole transport sublayer (HTL2) in the direction perpendicular to the emission layer (EML) accounts for 30% of d or less than 30% of d.

In the embodiment of the present application, the second hole transport sublayer (HTL2) is provided in the light emitting device, and the material of the second hole transport sublayer (HTL2) is the functional material. After the light emitting device is stored or used at high temperature for a period of time, the functional material in the second hole transport sublayer (HTL2) can crystallize. The crystallization structure can delay the aging of the hole transport material of the hole transport sublayer, thereby improving the problem that holes are hard to transport to the emission layer due to the aging of the hole transport material, and improving the efficiency of the hole transport and injection into the emission layer. Therefore, the hole injection and the electron injection in the emission layer can maintain a relatively balanced state, which can effectively slow down the reduction of the efficiency of the light emitting device, thereby prolonging the service life of the light emitting device under high temperature conditions.

In some embodiments of the present application, as shown in FIG. 4, the hole auxiliary layer includes an electron blocking sublayer (Prime), a first hole transport sublayer (HTL) and a hole injection sublayer (HIL). The first hole transport sublayer (HTL) is located on a side of the electron blocking sublayer (Prime) facing away from the emission layer EML, and the hole injection sublayer (HIL) is located between the first hole transport sublayer (HTL) and the anode (AN). The material of the electron blocking sublayer (Prime) includes an electron blocking material and the functional material.

In some embodiments of the present application, the proportion of the functional material in the material of the electron blocking sublayer is in a range of 2% to 3%.

The specific structure of the electron blocking material in the electron blocking sublayer is not limited here, and may be determined according to actual conditions.

In the embodiment of the present application, an appropriate amount of functional material is doped in the electron blocking sublayer, so that the electron blocking sublayer can block electrons from being transported to the anode, and at the same time, can improve the rate of the hole transport to the emission layer to a large extent. Therefore, the hole injection and the electron injection in the emission layer can maintain a relatively balanced state, which can effectively slow down the reduction of the efficiency of the light emitting device, thereby prolonging the service life of the light emitting device under high temperature conditions.

In some embodiments of the present application, the functional material includes a compound with a planar configuration.

It should be noted that the compound with the planar configuration means that the spatial constructions of the compound are located in one plane or the spatial constructions of the main structure of the compound are located in one plane.

In some embodiments, the configuration of the functional material provided by the embodiments of the present application further has certain symmetry and regularity, which helps the functional material to crystallize at a preset temperature.

In some embodiments, the functional materials provided by the embodiments of the present application may include free radical polymerization products obtained by free radical polymerization.

In some embodiments, the functional material provided by the embodiments of the present application may include inorganic substances with the crystallization property.

In some embodiments of the present application, the functional material includes a combination of one or more of butadiene compounds, alkoxy-substituted diphenylamine compounds, and coupled triphenylamine compounds.

Exemplary, the configuration of functional material can include

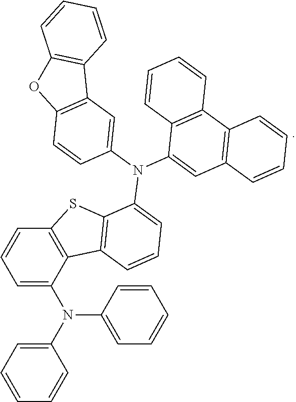 [SMILES: c1ccc(N(c2ccccc2)c2cccc3sc4c(N(c5ccc6oc7ccccc7c6c5)c5cc6ccccc6c6ccccc56)cccc4c23)cc1]

Exemplary, the configuration of functional material can include

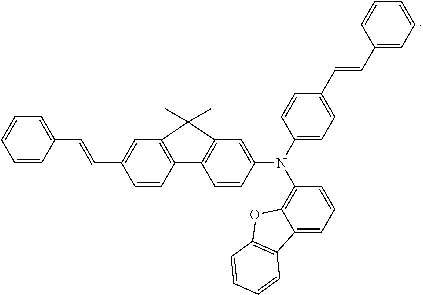 [SMILES: CC1(C)c2cc(/C=C/c3ccccc3)ccc2-c2ccc(N(c3ccc(/C=C/c4ccccc4)cc3)c3cccc4c3oc3ccccc34)cc21]

In some embodiments of the present application, as shown in FIG. 1 to FIG. 4, the light emitting device further includes a cathode (CA) located on a side of the emission layer (EML) facing away from the hole auxiliary layer.

In an exemplary embodiment, the light emitting device further includes a hole blocking layer (HBL) and an electron transport layer (ETL) between the emission layer (EML) and the cathode (CA).

The light emitting device may further include other film layers or structures. Here, only the structures related to the idea of the present application are introduced. For other structures included in the light emitting device, reference may be made to the introduction in related technologies.

The relevant test data of the light emitting device provided by the embodiment of the present application will be described below by taking the light emitting device as shown in FIG. 1 as an example.

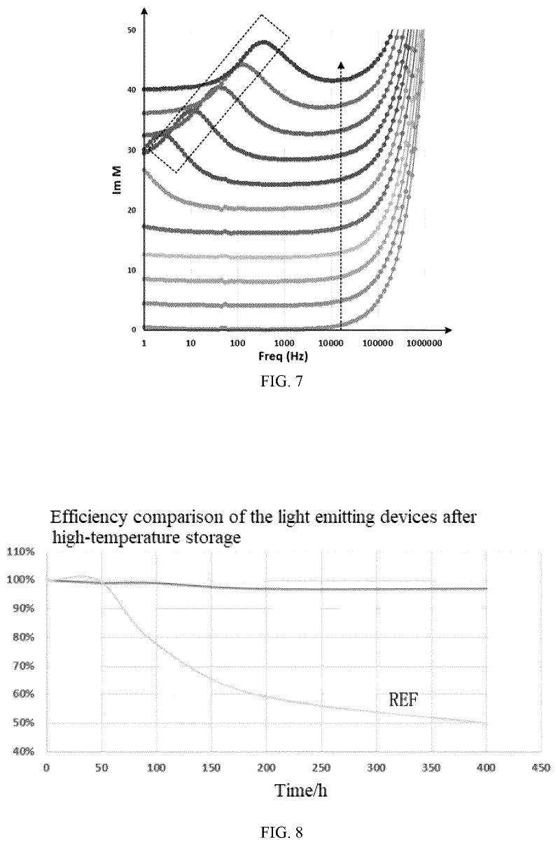

FIG. 6 shows impedance spectrum data of the light emitting device in the related art before a reliability test (such as a storage test under high temperature conditions). FIG. 7 shows impedance spectrum data of the light emitting device in the related art after a reliability test (such as a storage test under high temperature conditions). In FIG. 6 and FIG. 7, the peaks in the elliptical dotted circle indicate the occurrence of the hole transport, and the peaks in the rectangular dotted blocks indicate the occurrence of the electron transport. As can be seen from the comparison between FIG. 6 and FIG. 7, after the reliability test, the transport rate of holes in the light emitting device is significantly reduced, resulting in an imbalance of holes and electrons injected into the emission layer, resulting in a strong triplet-polar annihilation (TPA effect), reducing the luminous efficiency of the device. The direction indicated by the arrow in FIG. 6 and FIG. 7 represents increase of the test voltage of the light emitting device.

FIG. 5 shows the comparison of the crystallization property of the hole transport material in the related art and that of the functional material provided by the embodiment of the present application under the condition of 105° C. 1-1 represents the hole transport material in the related art, and 1-2 represents the functional material provided by the embodiment of the present application. As can be seen from FIG. 5, the crystallization property of the functional material provided by the embodiments of the present application becomes stronger as time elapses.

TABLE 1
Comparison of test data of the light emitting device in the related
art and that of the light emitting device of the present application

| | | | | Efficiency- |
|---|---|---|---|---|
| Time/h | Voltage | Efficiency | Voltage-REF | REF |
| 0 | 100% | 100% | 100% | 100% |
| 48 | 100% | 99% | 99% | 100% |
| 96 | 102% | 99% | 124% | 79% |
| 192 | 104% | 97% | 130% | 60% |
| 400 | 105% | 97% | 135% | 50% |

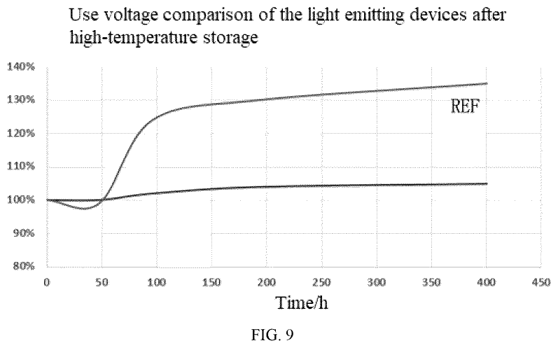

Among them, the one labeled with ‘REF’ is the light emitting device in the related art, and the other one is the light emitting device of the present application. It should be noted that the data in Table 1, FIG. 8 and FIG. 9 are all described by taking the structure of the light emitting device shown in FIG. 1 as an example.

Based on the data in FIG. 8 in combination with the data in Table 1, it can be seen that after the light emitting device in the related art and the light emitting device of the present application are stored under high temperature conditions for the same time, as the high temperature storage time increases, the real-time luminous efficiency of the light emitting device of the present application is slightly improved, while the luminous efficiency of the light emitting device in the related art is significantly reduced.

Based on the data in FIG. 9 in combination with the data in Table 1, it can be seen that after the light emitting device in the related art and the light emitting device of the present application are stored under high temperature conditions for the same time, as the high temperature storage time increases, the real-time use voltage of the light emitting device of the present application is slightly increased, while the use voltage of the light emitting device in the related art is greatly increased, and the power consumption is significantly increased.

When the light emitting device in the related art is stored at 105° C. for 96 hours, the efficiency of the device decreases by 21.2%, and the voltage increases by 23.6%, which ultimately leads to a significant reduction in the service life of the device. However, when the light emitting device provided by the embodiment of the present application is stored at 105° C. for more than 200 hours, the efficiency of the light emitting device is only reduced by about 3.2%, and the life of the light emitting device is significantly improved.

Embodiments of the present application provide a display apparatus including the light emitting device as described above.

The display apparatus may be a flexible display apparatus (also known as a flexible screen), or a rigid display apparatus (i.e., a display apparatus that cannot be bent), which is not limited here. The display apparatus may be an OLED (Organic Light Emitting Diode) display apparatus, and may also be any product or component with a display function such as a TV, a digital camera, a mobile phone, and a tablet computer including an OLED. The display apparatus has the advantages of good display effect, long service life, high stability and the like.

The above are merely exemplary implementations of the present disclosure, but the protection scope of the present disclosure is not limited thereto. Any changes or substitutions easily conceived by those skilled in the art based on the contents of the present disclosure fall within the protection scope of the present disclosure. Therefore, the protection scope of the present disclosure shall be defined by the appended claims.

1. A light emitting device, comprising:
an anode;
an emission layer located on a side of the anode; and
a hole auxiliary layer located between the anode and the emission layer;
wherein at least one of the emission layer and the hole auxiliary layer comprises a functional material, and the functional material is configured to be crystallizable at a preset temperature and improve hole injection property.

2. The light emitting device according to claim 1, wherein the preset temperature is greater than or equal to 105° C.

3. The light emitting device according to claim 1, wherein a glass transition temperature of the functional material is less than 105° C.

4. The light emitting device according to claim 1, wherein a material of the emission layer comprises the functional material, a guest material and at least one host material.

5. The light emitting device according to claim 4, wherein a proportion of the functional material in the material of the emission layer is in a range of 0.1% to 0.2%.

6. The light emitting device according to claim 4, wherein the material of the emission layer comprises at least two host materials, absolute value of a difference of highest occupied molecular orbital (HOMO) energy values of every two host materials is less than or equal to 0.1 eV.

7. The light emitting device according to claim 1, wherein the hole auxiliary layer comprises a first hole transport sublayer and a hole injection sublayer, and the hole injection sublayer is located on a side of the first hole transport sublayer facing away from the emission layer;
wherein a material of the first hole transport sublayer comprises a hole transport material and the functional material.

8. The light emitting device according to claim 7, wherein a proportion of the functional material in the material of the first hole transport sublayer is in a range of 20% to 30%.

9. The light emitting device according to claim 1, wherein the hole auxiliary layer comprises a first hole transport sublayer, a second hole transport sublayer and a hole injection sublayer, and the hole injection sublayer is located on a side of the first hole transport sublayer facing away from the second hole transport sublayer, the second hole transport sublayer is located between the first hole transport sublayer and the emission layer;
wherein at least one of the first hole transport sublayer and the second hole transport sublayer comprises the functional material.

10. The light emitting device according to claim 9, wherein the first hole transport sublayer comprises a hole transport material, and the second hole transport sublayer comprises the functional material, wherein a ratio of a thickness of the second hole transport sublayer in a direction perpendicular to the emission layer to a thickness of the first hole transport sublayer in the direction perpendicular to the emission layer is less than or equal to 3:7.

11. The light emitting device according to claim 1, wherein the hole auxiliary layer comprises an electron blocking sublayer, a first hole transport sublayer and a hole injection sublayer, and the first hole transport sublayer is located on a side of the electron blocking sublayer layer facing away from the emission layer, the hole injection sublayer is located between the first hole transport sublayer and the anode;
wherein a material of the electron blocking sublayer comprises an electron blocking material and the functional material.

12. The light emitting device according to claim 11, wherein a proportion of the functional material in the material of the electron blocking sublayer is in a range of 2% to 3%.

13. The light emitting device according to claim 1, wherein the functional material comprises a compound with a planar configuration.

14. The light emitting device according to claim 13, wherein the functional material comprises a combination of one or more of butadiene compounds, alkoxy-substituted diphenylamine compounds, and coupled triphenylamine compounds.

15. The light emitting device according to claim 13, wherein the light emitting device further comprises a cathode, and the cathode is located on a side of the emission layer facing away from the hole auxiliary layer.

16. A display apparatus, comprising light emitting device, wherein light emitting device comprises:
an anode;
an emission layer located on a side of the anode; and
a hole auxiliary laver located between the anode and the emission layer;
wherein at least one of the emission laver and the hole auxiliary laver comprises a functional material, and the functional material is configured to be crystallizable at a preset temperature and improve hole injection property.
